(19) United States
(12) Patent Application Publication
(10) Pub. No.: US 2006/0194419 A1
(43) Pub. Date: Aug. 31, 2006

(54) Crystalline-si-layer-bearing substrate and its production method, and crystalline si device

(76) Inventor: Yasushi Araki, Kanagawa-ken (JP)

Correspondence Address: SUGHRUE MION, PLLC, 2100 PENNSYLVANIA AVENUE, N.W., SUITE 800, WASHINGTON, DC, 20037, US

(21) Appl. No.: 10/552,513

(22) PCT Filed: Apr. 6, 2005
(86) PCT No.: PCT/JP04/04935

§ 371 Date: Oct. 6, 2005

(30) Foreign Application Priority Data
Apr. 7, 2003 (JP) 2003-102481

(51) Int. Cl. H01L 21/20

(52) U.S. Cl. 438/489

(57) ABSTRACT

A method for producing a substrate having a crystalline Si layer comprising the steps of forming an amorphous Si layer on a plastic substrate, and irradiating the amorphous Si layer with a laser beam to crystallize the amorphous Si, wherein the plastic substrate has light transmittance of 30 to 100% at an oscillation wavelength of the laser beam.

### FIELD OF THE INVENTION

The present invention relates to a method for producing a crystalline-Si-layer-bearing substrate, a crystalline-Si-layer-bearing substrate produced by such a method, and a crystalline Si device comprising a crystalline-Si-layer-bearing substrate.

### BACKGROUND OF THE INVENTION

Crystalline Si devices obtained by crystallizing an amorphous Si layer formed on a glass plate by the irradiation of excimer laser or solid laser have performance, which has recently been drastically improved. The crystalline Si devices constitute, for instance, liquid crystal displays and their peripheral driving circuits, making it possible to introducing one-bit SRAMs in pixels. Attempts have been made to provide the crystalline Si devices with higher performance by optimizing conditions such as the thickness of an amorphous Si layer formed on a glass plate, the energy and overlapping ratio of an irradiated laser beam, etc.

Because of demand for flexible displays, the formation of crystalline Si on plastic films in place of glass plates has also been proposed. For instance, JP 2002-221707 A proposes a thin-film laminate device having crystalline Si formed by irradiating an SiO₂ layer formed by a sputtering method, a vapor deposition method, a CVD method, etc. on a PES film with an excimer laser beam. It has been found, however, that if an SiO₂ layer on a plastic film substrate is irradiated with a laser beam at the same frequency as onto the glass plate and at as high an overlapping ratio as 99%, to increase the crystallinity of Si, most plastic film substrates are highly likely to be damaged. If the laser beam irradiation were carried out at a lower frequency, the problem of damaging the plastic film substrates would be able to be overcome. However, it would drastically decrease the production efficiency of the crystalline Si devices, failing to meet production cost requirements.

### OBJECTS OF THE INVENTION

Accordingly, an object of the present invention is to provide a method for producing a high-performance substrate having a crystalline Si layer with high efficiency.

Another object of the present invention is to provide a substrate having a crystalline Si layer obtained by such a method.

A further object of the present invention is to provide a crystalline Si device comprising such a substrate having a crystalline Si layer.

### SUMMARY OF THE INVENTION

As a result of intense research in view of the above objects, the inventor has found that (1) when an amorphous Si layer formed on a plastic substrate is crystallized by laser irradiation, a laser beam easily penetrates the amorphous Si layer with a thickness for use in high-performance crystalline Si devices; that (2) a penetrating light is absorbed by the plastic substrate to generate heat, which damages the plastic substrate and thus extremely deteriorates the performance of the crystalline Si device; and that (3) when a plastic substrate having light transmittance of 30% or more at a laser oscillation wavelength is used, the damage of the plastic substrate by the laser beam penetrating through the amorphous Si layer can be prevented, thereby providing a high-performance crystalline Si device with high production efficiency. The present invention has been accomplished by these findings.

To obtain a high-quality crystalline Si on a plastic substrate, it is preferable to crystallize the amorphous Si by using a laser outputting a laser beam having an extremely small pulse width at large energy. A laser oscillation wavelength used for such an object is preferably 450 nm or less, more preferably 310 nm or less, most preferably 250 nm or less. However, usual plastic substrates have low light transmittance to such laser beam, or are deteriorated because of extremely low heat resistance even if they permit the laser beam to transmit.

The inventor has discovered that when a plastic substrate having light transmittance of 30 to 100% at a laser oscillation wavelength, such as amorphous polyolefins and polyethersulfone, is used, the amorphous Si can be crystallized without suffering from damage. The transmittance of the plastic substrate to a laser beam is preferably 50 to 100%, more preferably 70 to 100%, further preferably 80 to 100%, most preferably 90 to 100%.

The objects of the present invention can be achieved by the following means.

(1) A method for producing a substrate having a crystalline Si layer comprising the steps of forming an amorphous Si layer on a plastic substrate, and irradiating the amorphous Si layer with a laser beam to crystallize the amorphous Si, wherein the plastic substrate has light transmittance of 30 to 100% at an oscillation wavelength of the laser beam.

(2) The method of (1) for producing a substrate having a crystalline Si layer, wherein the plastic substrate has light transmittance of 50 to 100%.

(3) The method of (1) or (2) for producing a substrate having a crystalline Si layer, wherein the amorphous Si layer has a thickness of 1 to 2000 nm.

(4) The method of any one of (1) to (3) for producing a substrate having a crystalline Si layer, wherein the oscillation wavelength of the laser beam is 140 to 450 nm.

(5) The method of any one of (1) to (4) for producing a substrate having a crystalline Si layer, wherein the laser beam is a pulse laser beam having a pulse width of 1 picosecond to 1 millisecond.

(6) The method of any one of (1) to (5) for producing a substrate having a crystalline Si layer, wherein the energy density of a laser beam in one scan is 100 to 500 mJ/cm².

(7) The method of any one of (1) to (6) for producing a substrate having a crystalline Si layer, wherein the overlapping ratio of the laser irradiation is 80 to 100%.

(8) The method of any one of (1) to (7) for producing a substrate having a crystalline Si layer, wherein the laser beam is a pulse laser beam having a frequency of 1 to 1000 Hz.

(9) The method of any one of (1) to (8) for producing a substrate having a crystalline Si layer, wherein the laser beam is an excimer laser beam.

(10) The method of any one of (1) to (9) for producing a substrate having a crystalline Si layer, wherein the laser is a XeCl excimer laser.

(11) The method of any one of (1) to (10) for producing a substrate having a crystalline Si layer, wherein the laser is a KrF excimer laser.

(12) The method of any one of (1) to (11) for producing a substrate having a crystalline Si layer, wherein the plastic substrate is made of amorphous polyolefin or polyethersulfone.

(13) The method of any one of (1) to (12) for producing a substrate having a crystalline Si layer, wherein the plastic substrate is made of a cycloolefin polymer represented by the following general formula (1): 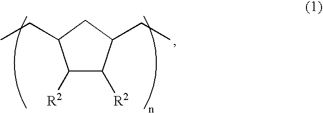
or by the following general formula (2): 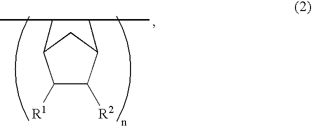
wherein R¹ and R² independently represent a hydrogen atom, a nonpolar group, a halogen atom, a hydroxyl group, an ester group, an alkoxy group, a cyano group, an amide group, an imide group or a silyl group; n represents an integer of 1 to 100,000; and R¹ and R² may be connected to each other to form a mono- or poly-cyclic ring, provided that R¹ and R² do not form a 5-membered, unsubstituted, saturated, monocyclic hydrocarbon.
(14) A substrate having a crystalline Si layer produced by the method recited in any one of (1) to (13).
(15) The substrate of claim (14) having a crystalline Si layer, wherein the plastic substrate is provided with an insulating thin film having a thickness of 10 nm to 10 μm on at least one surface.
(16) A crystalline Si device comprising the substrate of (14) or (15) having a crystalline Si layer.

### BRIEF DESCRIPTION OF THE DRAWINGS

FIG. 1 is a transmission spectrum of a substrate made of polyethersulfone A used in Reference Example 1;

FIG. 2 is a schematic view showing a pattern of a polycrystalline Si layer;

FIG. 3 is a schematic view showing patterns of a gate oxide film and a gate electrode formed on a polycrystalline Si layer;

FIG. 4 is a schematic view showing a pattern of contact holes provided in the SiO₂ layer formed on the gate electrode;

FIG. 5 is a schematic view showing Al electrode pads formed on a thin-film transistor;

FIG. 6 is a transmission spectrum of a substrate made of amorphous polyolefin A used in Example 1;

FIG. 7 is a transmission spectrum of a substrate made of polyethersulfone B used in Example 2;

FIG. 8 is a transmission spectrum of a substrate made of amorphous polyolefin B used in Example 3;

FIG. 9 is a transmission spectrum of a substrate made of polyethersulfone C used in Example 4; and

FIG. 10 is a transmission spectrum of a substrate made of amorphous polyolefin C used in Example 5.

### DETAILED DESCRIPTION OF THE PREFERRED EMBODIMENTS

[1] Substrate Having Crystalline Si Layer

The substrate having a crystalline Si layer (simply called “crystalline-Si-layer-bearing substrate”) according to the present invention may use any plastic substrate, as long as it has a light transmittance of 30% or more, at oscillation wavelengths of irradiated laser beams. Examples of materials for the plastic substrate include polysulfones such as polyethersulfone and polyphenylenesulfone; polyphenylene sulfide; crystalline or amorphous polyolefins such as polyethylene, polypropylene, polybutene, chlorinated polyethylene, polymethylpentene and norbornene resins; polyesters such as polyethylene terephthalate, polybutylene terephthalate, polyethylene naphthalate and diallyl phthalate; polycarbonates; acrylic resins such as polymethyl methacrylate and polyacrylonitrile; vinyl polymers and copolymers such as ethylene-vinyl chloride copolymers, ethylene-vinyl acetate copolymers, polyvinyl chloride, polyvinylidene chloride, polyvinyl ether, polyvinyl acetate, polyvinyl alcohol, ethylene-vinyl alcohol copolymers, polyvinylphenol and polyvinyl butyral; polyamides; polyimides such as polyamide-imide, polyetherimide and polyaminobismaleimide; polyethers such as polyetheretherketone and polyphenylene ethers; styrene resins such as polystyrene and polymethyl styrene; fluororesins; silicone resins; polytriazine; polyacetal; cellulose plastics such as cellulose acetate, cellophane and nitrocellulose; ABS resins; ABS/PVC alloys; SAN resins; AES resins; AAS resins; polyallylamine; petroleum resins; polybutadiene; thermoplastic elastomers; thermoplastic polyurethanes; thermosetting resins such as epoxy resins, phenol resins, urea resins, melamine resins, furan resins, guanamine resins, ketone resins (polycyclohexanone), etc.

Preferable among them are polyethersulfone, amorphous polyolefins such as norbornene resins. Particularly preferable amorphous polyolefins are cycloolefin polymers represented by the following the general formula (1) or (2): 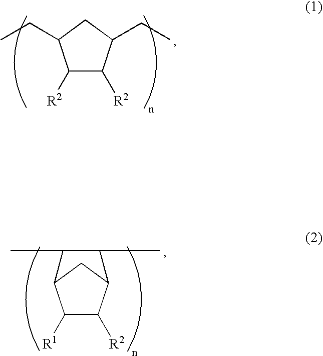
wherein R¹ and R² independently represent a hydrogen atom, a nonpolar group, a halogen atom, a hydroxyl group, an ester group, an alkoxy group, a cyano group, an amide group, an imide group or a silyl group; n represents an integer of 1 to 100,000; and R¹ and R² may be connected to each other to form a mono- or poly-cyclic ring, provided that R¹ and R² do not form a 5-membered, unsubstituted, saturated, monocyclic hydrocarbon. The preferred nonpolar group is a hydrocarbon group such as aliphatic hydrocarbon group, an aromatic hydrocarbon group, etc. Some of the cycloolefin polymers having such structures may be called norbornene resins.

The plastic substrate for forming a crystalline Si layer has a transmittance of 30 to 100% to a laser beam having an oscillation wavelength of 140 to 450 nm. The laser beam transmittance is preferably 50 to 100%, more preferably 70 to 100%, further preferably 80 to 100%, most preferably 90 to 100%.

The plastic substrate is preferably provided with an insulating thin film having a thickness of 10 nm to 10 μm on at least one surface. The insulating thin film serves to retard heat generated in the amorphous Si layer during laser irradiation from being transmitted to the plastic substrate. The thickness of the insulating thin film is more preferably 100 nm to 10 μm, further preferably 100 nm to 1 μm, most preferably 100 nm to 800 nm, particularly 300 nm to 600 nm. Though not particularly restrictive, the insulating thin film formed on the plastic substrate is preferably an inorganic thin film of SiO₂, Si₃N₄, Al₂O₃, AlN, Ta₂O₅, TiO₂, etc.

The crystalline-Si-layer-bearing substrate can be obtained by crystallizing an amorphous Si layer formed on the plastic substrate by laser irradiation. The thickness of the amorphous Si layer is preferably 1 nm to 10 μm, more preferably 10 nm to 1000 nm, further preferably 10 nm to 80 nm, most preferably 10 nm to 50 nm, particularly 20 nm to 50 nm. The thinner amorphous Si layer can provide a higher crystallinity of Si and a larger light transmittance, resulting in larger effects of the present invention.

[2] Production of Crystalline-Si-Layer-Bearing Substrate

The methods for forming an amorphous Si layer on the plastic substrate are not particularly restrictive, and their preferred examples are a sputtering method, a reactivity sputtering method, an electron-beam evaporation method, a thermal CVD method, a plasma CVD method, a plasma-enhanced CVD method, a CAT CVD method, a laser beam CVD method, etc.

The formed amorphous Si layer is crystallized by the irradiation of a laser beam. The crystallization by a laser beam provides different degrees of crystallinity depending on which optical system is used to emit a laser beam. As long as the crystallinity of Si can be increased, any optical system may be used, but its preferred examples are a spot beam optical system, an optical system having a spot beam optical system scanned by a galvanometer mirror, a line beam optical system, etc. A line beam optical system for emitting a fine line beam of 10 μm or less is preferable to increase the crystallinity of Si.

A catalyst such as Ni may be used to improve the crystallization of Si. In this case, the catalyst is not restricted to Ni, but may be Au, Pt, Al, Ge, Ga, In, Ti, Pb, Sn, Bi, Zn, Cd, Hg, Cu, Ag, Pd, Co, Rh, Ir, Fe, Ru, Mn, Re, Cr, Mo, W, V, Nb, Ta, Zr, Hf, Sc, Y, Mg, Ca, Sr, Ba, Ra, Li, Na, K, Rb, Cs, Fr, etc. During the crystallization of Si, a mask may be disposed in a desired place, or a local crystallization method may be utilized.

In the laser beam irradiation, the laser oscillation wavelength is preferably 140 nm to 450 nm, because if the oscillated laser beam has a short wavelength, the amorphous Si has a large absorption coefficient, resulting in less laser beam reaching the substrate. The laser oscillation wavelength is more preferably 140 nm to 400 nm, further preferably 140 nm to 310 nm, particularly 140 nm to 250 nm.

Because energy concentrated in a short period of time causes less damage to the substrate, it is possible to irradiate a pulse laser beam. The pulse width of the pulse laser beam is preferably 1 picosecond to 1 millisecond, more preferably 1 nanosecond to 1 microsecond, further preferably 1 nanosecond to 100 nanoseconds, particularly 5 nanoseconds to 30 nanoseconds.

The pulse laser beam preferably has a frequency of 1 Hz or more. Though increase in the pulse frequency leads to the improvement of production efficiency, it is also likely to cause damage to usual substrates. However, the crystalline-Si-layer-bearing substrate of the present invention can effectively prevent such damage. The frequency of the pulse laser beam is more preferably 10 Hz or more, further preferably 50 Hz or more, still further preferably 100 Hz or more, most preferably 300 Hz or more, particularly 1 kHz or more. Though the higher frequency of the pulse laser beam is more preferable, its upper limit is preferably about 100 MHz.

To irradiate a surface of a large-area substrate, the substrate is scanned by a laser beam, which may or may not be pulse. The laser beam energy density in one scanning is preferably 100 to 500 mJ/cm², more preferably 200 to 400 mJ/cm². It is preferable that scanning regions of the laser beam are partially overlapped. When the laser beam is scanned pluralities of times with its irradiation regions partially overlapped, a percentage of an overlapped irradiation area of the scanned laser beams to a one-scan irradiation area of the laser beam is called “overlapping ratio.” The overlapping ratio of the irradiated laser beam is preferably 80% or more, more preferably 90% or more, further preferably 95% or more, particularly 99% or more.

The types of the laser used are not particularly restrictive, and their preferred examples are an excimer laser, a flash-lamp-excited YAG laser, an LD-excited YAG laser, a large-output LD laser, a CO₂ laser, a titanium-sapphire femtosecond laser, etc. Among them, an excimer laser, a large-output YAG laser and their harmonics are particularly preferable. A laser diode and a large-output femtosecond YAG laser, which are rapidly developing recently, are also preferably usable.

There are many types of excimer lasers depending on how to produce excimer. Preferred examples of the excimer lasers include ArF, KrF, XeF, ArCl, KrCl, XeCl, KrBr, XeBr, Xe₂, Kr₂, Ar₂, ArO, KrO, XeO, Kr₂F, Xe₂Cl, HgCl, HgBr, HgI, etc. More preferable among them are XeCl and KrF, particularly KrF.

Desired patterning is conducted on the crystalline Si layer formed on the substrate. Though not particularly restrictive, the patterning is preferably carried out by a lithography system using usual aligner or stepper. In addition to a usual UV exposure lithography method, an electron beam lithography method, an EUV lithography method, an X-ray lithography method, etc. are preferable. In addition to the lithography method, a printing method and a transfer method may be used. The patterning may not necessarily be conducted directly on the crystalline Si layer as described above, but may be conducted on the amorphous Si layer, which is then annealed to be a crystalline Si layer by a laser beam, etc.

The patterning of Si is carried out preferably by etching, particularly by dry etching. Though not particularly restrictive, the dry etching preferably uses CF₄, SF₆, NF₃, CBrF₃, CCl₄, SiCl₄, PCl₃, BCl₃, Cl₂, HCl, etc., particularly a CF₄ gas. Of course, a wet etching may be conducted in place of the dry etching. Etchants used for the wet etching may be nitric acid, fluoric acid, hydrochloric acid, acetic acid, phosphoric acid, sulfuric acid and their mixed acids, etc. As long as they act as etchants to Si, they may be mixed at any combination and ratio, but particularly preferable are a mixed acid of glacial acetic acid, nitric acid and fluoric acid, and a mixed acid of nitric acid and fluoric acid. Etchants for dissolving Si may be in the form of an alkaline solution. Though not particularly restrictive, alkaline etchants may be KOH, NaOH, Ca(OH)₂, etc. In the etching, photoresists suitable for each etchant are preferably selected.

A dopant may be added to the crystalline Si. The preferred dopants include P, B, As, Sb, Ga, In, N, Bi, Ti, Al, etc. The crystalline Si may be doped with other elements such as H, O, C, Ge, etc. for the other purpose than adjusting its resistivity.

Though not particularly restrictive, the amount of the above dopant added to the crystalline Si is preferably 1×10¹⁰ to 5×10²² atom/cm³, more preferably 1×10¹⁴ to 5×10²¹ atom/cm³. An ion injection method is preferably used for doping because of precise control, though other doping methods such as a solid phase diffusion method, a liquid phase diffusion method, a gas phase diffusion method, etc. may be used. Though not particularly restrictive, the driving of dopants is preferably conducted by laser irradiation. Of course, heat driving is also usable.

[3] Crystalline Si Device

The crystalline Si device of the present invention is not particularly limited, as long as it comprises the above substrate having a crystalline Si layer. The crystalline Si device of the present invention can constitute, for instance, basic devices such as diodes, transistors, thyristors, capacitors, resistors, photo-functional devices, etc. The diodes may be double-base diodes, Gunn diodes, IMPATT diodes, Esaki diodes, etc. The thyristors are preferably reverse-blocking diode pnpn switches, reverse-blocking triode thyristors, gate-turnoff (GTO) thyristors, reverse-conducting diode thyristors, reverse-conducting triode RCT, bidirectional DIAC, bidirectional TRIAC, reverse-blocking diode LASCR, reverse-blocking triode LASCR, etc. The transistors are preferably bipolar transistors and FET, and the preferred FET is MOSFET. In addition to usual MOSFET, nonvolatile MOSFET memories such as floating-gate, nonvolatile MOSFET memories, ferroelectric MOSFET memories, junction FET, Schottky gate FET, electrostatic induction transistors, etc. may be included. The photo-functional devices are preferably photodiodes, avalanche photodiodes, phototransistors, etc.

The above basic devices may be used to constitute basic logic gates for sequential circuits, combination circuits, logic circuits, etc. The basic logic gates may be NOT gates, AND gates, OR gates, NAND gates, NOR gates, etc. The logic circuits may include sequential circuits and combination circuits. The combination circuits may be AND-OR, OR-AND, NAND, NOR, AND-exclusive OR, ROM, PLA, etc. These combination circuits may constitute adder circuits such as binary adder circuits, decimal adder circuits, complementers, subtracter circuits, high-speed, carry-look-ahead adders, high-speed carry-skip adders, high-speed, carry-detection adders, high-speed, carry-save adders, conditional adders, etc. The above basic devices may be used to constitute comparators such as parallel comparators and series comparators, encoders, decoders, code converters, multiplexers, etc.

The sequential circuit may be synchronous or asynchronous, but synchronous one is more preferable. The sequential circuit is particularly a flip-flop. The trigger of the flip-flops may be edge trigger or master-slave trigger. Preferred examples of the flip-flops include JK flip-flops, SR flip-flops, T flip-flops, D flip-flops, etc.

The above basic device may also constitute counters such as binary counters, 2n-ary counters, decimal counters, 10n-ary counters, ring counters, etc.; memory circuits such as static RAM, dynamic RAM, mask ROM, PROM, EPROM, EEPROM, ferroelectric memories, associative memories, CCD memories, etc.; high-gain amplifier circuits, output circuits, bias circuits, level shift circuits, negative feedback amplifier circuits, operational amplifier circuits, etc. The operational amplifier circuits can constitute various linear circuits and non-linear circuits. Preferred examples of the operational amplifiers are negative- or positive-phase, constant-multiplying amplifier circuits, adder/subtracter circuits, differentiating/integrating circuits, negative impedance converters, generalized impedance converters, etc.

[4] Production of Crystalline Si Device

The production of the crystalline Si device of the present invention will be explained, taking a particularly preferable self-aligned, top-gate thin-film transistor for example. Of course, the present invention is not restricted to this example, but may be applied to a non-aligned, top-gate or bottom-gate thin-film transistor as well as various basic devices described above.

In the production of the self-aligned, top-gate thin-film transistor, an amorphous Si layer is first formed on a plastic substrate, but it is preferable to form an inorganic insulating thin film such as SiO₂, Si₃N₄, Al₂O₃, etc., or an organic insulating thin film such as a polyimide, etc. on the plastic substrate in advance. The amorphous Si layer is formed on the plastic substrate or on the insulating film formed thereon, for instance, by a sputtering method, a reactive sputtering method, an electron beam evaporation method, a heat CVD method, a plasma CVD method, a plasma-enhanced CVD method, a CATCVD method, a laser CVD method, etc. During the film forming process, it is preferable to supply hydrogen. Hydrogen is preferable in that it terminates the dangling bonds of the amorphous Si. When too much hydrogen is included in the amorphous Si layer, however, it is discharged from the film as a gas in a subsequent laser irradiation process, resulting in film breakage, etc. Accordingly, under such film-forming conditions that too much hydrogen is absorbed in the amorphous Si layer, it is preferable to remove excess hydrogen from the amorphous Si by heating after film formation. Other unnecessary gases than hydrogen are also preferably removed together with hydrogen. The substrate is preferably heated before film formation.

A small amount of a p-type or n-type dopant is preferably added to the amorphous Si to adjust threshold voltage. The dopant may be added at the time of film forming, or it may be added after the formation of the amorphous Si film using an ion-injection apparatus. Though the type of the dopant is not particularly restrictive, the p-type dopant is preferably B, and the n-type dopant is preferably P or As. The amount of the dope is preferably 1×10¹¹ to 1×10²⁰ atom/cm³, more preferably 1×10¹² to 1×10¹⁸ atom/cm³, further preferably 1×10¹³ to 1×10¹⁵ atom/cm³.

In the case of conducting laser irradiation, the thin-film transistor preferably has a structure having no trap of electrons or holes in a source-drain direction. Thus, the thin-film transistor is irradiated with a laser beam such that the direction of a laser beam line is aligned with the source-drain direction, or such that a crystal grows in the source-drain direction. After the amorphous Si layer is crystallized by a laser beam, the resultant crystalline Si layer is patterned. The patterning method may be a dry etching or a wet etching. Particularly to obtain a channel width of 10 μm or less, the dry etching is preferable.

After patterning the crystalline Si layer, a gate oxide film and a gate electrode are formed thereon. Because the conditions of an interface between this gate oxide film and the crystalline Si layer extremely affect the performance of a thin-film transistor, a surface of the crystalline Si layer is preferably well cleaned by an RCA cleaning method, etc., and then subjected to a surface treatment such as a high-pressure steam treatment, hydrogen annealing, oxygen annealing, a hydrogen plasma treatment, an oxygen plasma treatment, etc. After the surface treatment, the gate oxide film is formed on the crystalline Si layer. Though not particularly restrictive, the gate oxide film is preferably a film of SiO₂, Si₃N₄, TaO₃, HfO₂, etc., or a laminate of their proper combinations. The thickness of the gate oxide film is preferably as small as possible in a range of preventing a leak current. Specifically, the thickness of the gate oxide film is preferably 10 nm to 200 nm, more preferably 30 nm to 150 nm, most preferably 50 nm to 100 nm.

The gate electrode is formed on the resultant gate oxide film. Materials for the gate electrode are preferably Al, Mo, Ta, W, polycrystalline Si, etc. More preferable among them are Al, Mo, Ta and W, because they make easy the driving of a dopant in the source/drain region by subsequent laser irradiation. Al is particularly preferable because of extremely low resistance. A laminate constituted by films of these materials is also preferable for the gate electrode. The thickness of the gate electrode is preferably 0.2 μm to 2 μm, more preferably 0.4 μm to 1 μm.

After the formation of the gate electrode, the gate oxide film and the gate electrode are patterned. The patterning is preferably carried out by dry etching or wet etching. When the gate width is 10 μm or less, the dry etching is particularly preferable. In the case of dry etching, CF₄+H₂, CHF₃, C₂F₆, etc. are preferabty used. In the case of wet etching, proper etchants are selected depending on the materials of the gate oxide film and the gate electrode. In the case of the gate oxide film made of SiO₂, it is preferable to use a mixed acid of nitric acid and fluoric acid, or a mixed acid of acetic acid, nitric acid and fluoric acid, and particularly preferable is buffered fluoric acid, which is a mixture of fluoric acid and sodium fluoride. In the case of the gate oxide film of Si₃N₄, it is preferable to use a mixed acid comprising a combination of two or more acids selected from the group consisting of nitric acid, fluoric acid, hydrochloric acid, acetic acid, phosphoric acid and sulfuric acid, at properly adjusted proportions, and particularly preferable is hot concentrated phosphoric acid.

After the patterning of the gate electrode or the gate oxide film, a dopant is added in a source/drain region. In this case, the thin-film transistor preferably has a lightly doped drain (LDD) structure or an offset structure. Without these structures, the source-drain portion is doped with P or As in the case of an n-type thin-film transistor, or B in the case of a p-type thin-film transistor, after the patterning of the gate electrode or the gate oxide film. The doping concentration is preferably 1×10¹⁹ to 1×10²² atoms/cm³. Of course, other dopants may be used. The addition of a dopant is preferably carried out by a method of injecting the dopant using an ion injection apparatus and then driving the dopant by laser irradiation; a method of heating the injected dopant in a furnace; a method of placing a solid source on a source-drain surface and melting the crystalline Si by laser irradiation; or a method of irradiating the crystalline Si with a laser beam in a chamber filled with a doping gas to conduct doping by melting the crystalline Si. After driving the dopant, the gate electrode is preferably protected by anodizing. When the thin-film transistor does not have an LDD structure or an offset structure, an interlayer dielectric film is preferably formed after the doping treatment.

The thin-film transistor having an LDD structure should have a low-dopant-concentration portion between a drain and a channel. The thin-film transistor may have a low-crystallinity amorphous portion in place of the low-dopant-concentration portion. The thin-film transistor having an offset structure should have a structure in which a high-dopant-concentration portion in a drain does not overlap the gate electrode. Methods for producing such structures are not particularly restrictive. The LDD or offset structure may be formed, for instance, by a slanted rotational injection method or by utilizing a sidewall. These structures may also be formed by oxidizing the sidewall of the gate electrode.

The thin-film transistor preferably has a silicide structure. The silicide is usually obtained by depositing a metal on a silicon surface, and heating them to form their compound. Preferable are silicides with metals such as titanium, cobalt, nickel, etc., though silicides with other metals may be used. Preferred examples of other metals than the above metals for forming silicides are Au, Pt, Al, Ge, Ga, In, Pb, Sn, Bi, Zn, Cd, Hg, Cu, Ag, Pd, Rh, Ir, Fe, Ru, Mn, Re, Cr, Mo, W, V, Nb, Ta, Zr, Hf, Sc, Y, Mg, Ca, Sr, Ba, Ra, Li, Na, K, Rb, Cs, Fr, etc., which may be used alone or in combination.

An interlayer dielectric film is preferably formed on the gate electrode. Though not particularly restrictive, interlayer dielectric materials are preferably SiO₂, Si₃N₄, polyimide, etc. The thickness of the interlayer dielectric film is preferably 0.1 μm to 10 μm, more preferably 0.2 μm to 5 μm, most preferably 0.4 μm to 1 μm.

After the formation of the interlayer dielectric film, contact holes are formed by patterning in portions corresponding to the gate electrode and the source or drain region. Smaller contact holes are more preferable for smaller thin-film transistors, though contact resistance increases as the contact holes become smaller. Because trouble is likely to occur at the contact holes, the contact holes are preferably slightly larger than the channels of the thin-film transistor. The patterning of the contact holes is preferably conducted by dry etching.

After the formation of the contact holes, a first wiring is formed. The first wiring is not limited to usual wiring, but may include electrodes of elements such as capacitors, etc. Though not particularly restrictive, materials for the first wiring are preferably Cr, Al, Cu, Au, W, Mo, Ta, Ni, Au, Ag, Pt and their alloys. Al, Cr and their alloys are particularly preferable. Particularly preferable are Al alloys containing several % of Ti, Al alloys containing several % of Si, and Al alloys containing 0.1% or more of Cu. The first wiring is preferably formed by dry etching using CCl₄, CF₄+H₂, etc. After the formation of the first wiring, an interlayer dielectric film and then a second wiring may be formed, and these processes may be repeated to form a multilayer wiring (electrode).

The present invention will be explained in more detail with reference to Examples below without intention of restricting the scope of the present invention.

### REFERENCE EXAMPLE 1

(1) Production of Crystalline-Si-Layer-Bearing Substrate

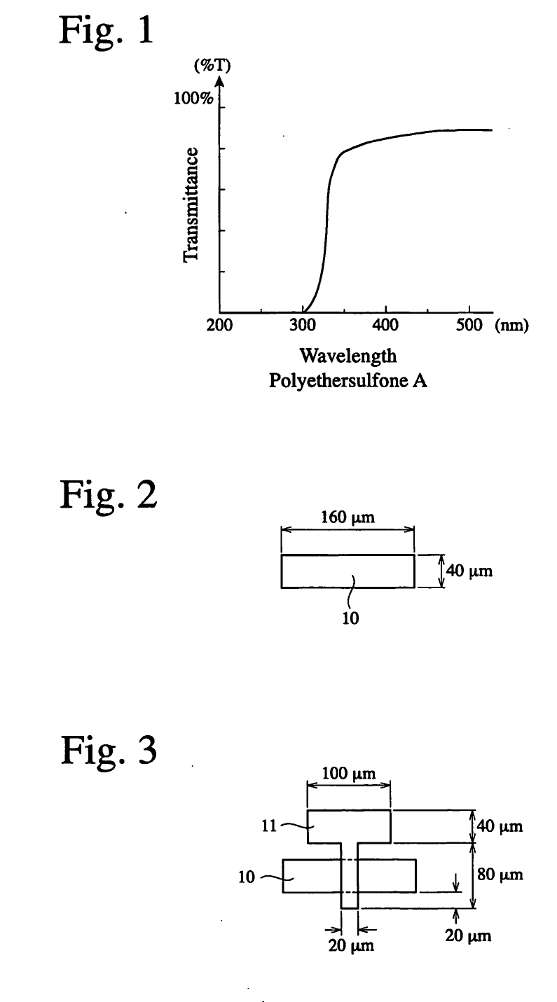

The transmission spectrum of a 200-μm-thick PES film (FS 1500, available from SUMITOMO BAKELITE Co., Ltd.) made of polyethersulfone A is shown in FIG. 1. A 0.5-μm-thick SiO₂ layer was formed on this PES film using a sputtering apparatus at RF of 400 W. Next, an amorphous Si layer having a thickness shown in Table 1 was formed using undoped polycrystalline Si at RF of 200 W. Using a XeCl excimer laser (370 mJ/cm²) or a KrF excimer laser (280 mJ/cm²), this amorphous Si layer was irradiated with a laser beam at the overlapping ratios and frequencies of laser beam shown in Table 1 to crystallize the amorphous Si, thereby producing a substrate having a polycrystalline Si layer.

(2) Production of Thin-Film Transistor

A polycrystalline Si layer of the resultant crystalline-Si-layer-bearing substrate was patterned to a shape shown in FIG. 2, using a photoresist OFPR800 and an etchant 1 (mass ratio of nitric acid:fluoric acid=50:1). Formed on the resultant polycrystalline Si layers 10 were a 0.1-μm-thick SiO₂ layer sputtered at RF of 400 W, and a 0.5-μm-thick Al—Si layer sputtered at DC of 400 W. The resultant SiO₂ layer and Al—Si layer were etched to a pattern as shown in FIG. 3 using a photoresist OFPR800 and an etchant 2 (mass ratio of fluoric acid:water=1:80), thereby forming a gate electrode (Al—Si) 11 on each polycrystalline Si layer 10 via the gate oxide film. Phosphorus was then injected into a source/drain region of the polycrystalline Si layer 10, using an ion-injection apparatus at an acceleration voltage of 20 keV and a dosing amount of 1×10¹⁴ atom/cm³. Next, it was irradiated with a XeCl excimer laser (370 mJ/cm²) or a KrF excimer laser (280 mJ/cm²) again to drive the dopant.

(3) Evaluation

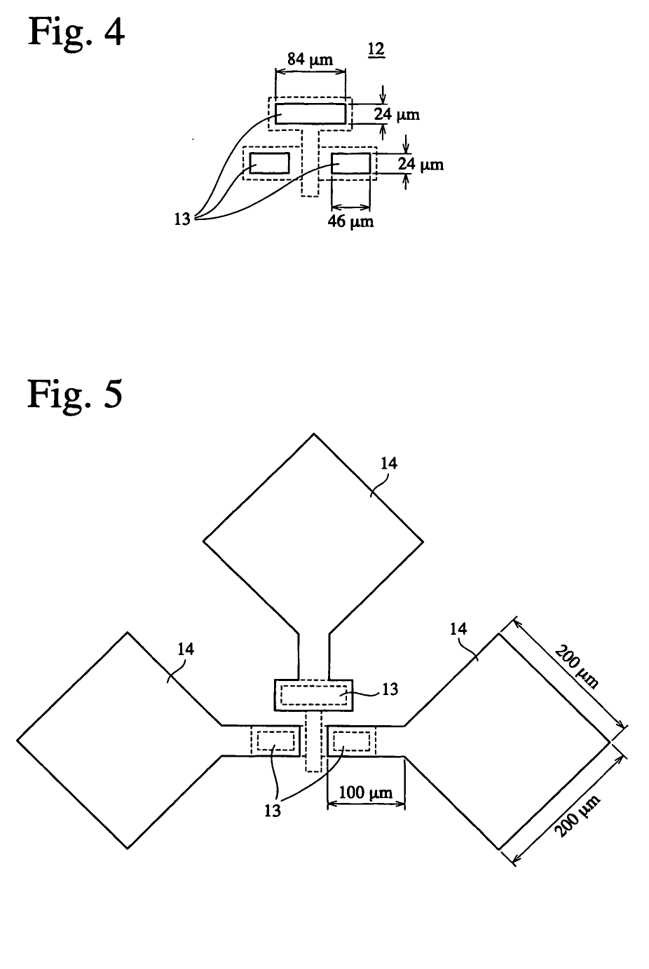

A 0.5-μm-thick SiO₂ layer 12 was formed on the above thin-film transistor by a sputtering method. The SiO₂ layer 12 was provided with contact holes 13 as shown in FIG. 4, and an Al electrode pad 14 was formed on each contact hole 13 as shown in FIG. 5. With these Al electrode pads 14 in contact with Picoprobe MODEL 7A-3ft (available from GGB Industries. Inc.) having a probe tip T-7-175 attached thereto, the electric characteristics of the thin-film transistor were measured using a source meter Keithley 2400 as a power source. A threshold voltage was determined from source/drain current characteristics relative to a gate voltage, and the carrier mobility of the polycrystalline Si was determined from the threshold voltage, and the source/drain current characteristics relative to the source/drain voltage. The results are shown in Table 1. When the substrate was completely damaged, Table 1 indicates “Substrate Damaged” in the column of carrier mobility.

TABLE 1

| | Thickness of | | Laser- | Laser | |
|---|---|---|---|---|---|
| | Amorphous Si | Type of | Overlapping | Frequency | Carrier Mobility |
| Sample No. | Layer (nm) | Laser | Ratio (%) | (Hz) | (cm²/V · s) |
| 1 | 150 | XeCl | 80 | 200 | Substrate Damaged |
| 2 | 50 | XeCl | 80 | 200 | Substrate Damaged |
| 3 | 80 | XeCl | 80 | 200 | Substrate Damaged |
| 4 | 150 | XeCl | 80 | 200 | Substrate Damaged |
| 5 | 150 | XeCl | 80 | 100 | Substrate Damaged |
| 6 | 150 | XeCl | 80 | 50 | Substrate Damaged |
| 7 | 150 | XeCl | 80 | 20 | 22 |
| 8 | 150 | XeCl | 80 | 10 | 20 |
| 9 | 80 | XeCl | 80 | 20 | Substrate Damaged |
| 10 | 80 | XeCl | 80 | 10 | 30 |
| 11 | 150 | XeCl | 90 | 20 | Substrate Damaged |
| 12 | 150 | XeCl | 90 | 10 | Substrate Damaged |
| 13 | 150 | XeCl | 90 | 5 | 34 |
| 14 | 80 | XeCl | 90 | 5 | Substrate Damaged |
| 15 | 150 | XeCl | 95 | 5 | Substrate Damaged |
| 16 | 150 | XeCl | 95 | 1 | 49 |
| 17 | 80 | XeCl | 95 | 1 | 57 |
| 18 | 50 | XeCl | 95 | 1 | 81 |
| 19 | 30 | XeCl | 95 | 1 | Substrate Damaged |
| 20 | 150 | XeCl | 99 | 1 | Substrate Damaged |
| 21 | 150 | XeCl | 99 | 0.1 | 63 |
| 22 | 80 | XeCl | 99 | 0.1 | 85 |
| 23 | 50 | XeCl | 99 | 0.1 | 110 |
| 24 | 30 | XeCl | 99 | 0.1 | 149 |
| 25 | 150 | KrF | 99 | 0.1 | 83 |
| 26 | 80 | KrF | 99 | 0.1 | 98 |
| 27 | 50 | KrF | 99 | 0.1 | 132 |
| 28 | 30 | KrF | 99 | 0.1 | 168 |
| 29 | 150 | KrF | 99 | 200 | Substrate Damaged |
| 30 | 80 | KrF | 99 | 200 | Substrate Damaged |
| 31 | 50 | KrF | 99 | 200 | Substrate Damaged |
| 32 | 30 | KrF | 99 | 200 | Substrate Damaged |

As is clear from Samples 1 to 4 in Table 1, the PES substrates are damaged when amorphous Si layers of 50 nm to 150 nm in thickness are crystallized at a laser frequency of 200 Hz and at a laser-overlapping ratio of 80%. Though Samples 5 and 6 indicate that the substrates are damaged even though the laser frequency is decreased to 50 Hz at an amorphous Si layer thickness of 150 nm, Samples 7 and 8 indicate that the substrates are not damaged when the laser frequency is decreased to 20 Hz or less at an amorphous Si layer thickness of 150 nm. Also, Sample 10 indicates that when the laser frequency is decreased to 10 Hz, the substrates are not damaged even though an amorphous Si layer has a thickness of 80 nm. The carrier mobility is larger in Sample 10 than in Sample 8 at the same overlapping ratio and frequency of laser beam. This proves that the thinner the amorphous Si layer, the higher the performance of the thin-film transistor. This tendency is true even in Samples 21 to 28 using an extremely decreased laser frequency.

This means that when thin amorphous Si layers are used to produce high-performance Si devices, the substrates are likely to be damaged, and that to avoid such damage, the laser frequency should be extremely decreased. The production efficiency at a laser frequency decreased to 0.1 Hz, for instance, is 1/3000 of the efficiency at usual 300 Hz, resulting in undesirable results in terms of production cost.

As the overlapping ratio increases from Sample 8 to Samples 12, 15 and 20, damage becomes likelier on the substrates, though TFT has higher performance. Though decrease in the laser frequency makes the damage of substrates unlikelier as is clear from the comparison of Samples 12 and 13, Samples 15 and 16, and Samples 20 and 21, too much decrease in the laser frequency undesirably results in decrease in the production efficiency.

It is clear from Samples 21 to 28 that a KrF excimer laser provides larger carrier mobility and thus higher performance to a thin-film transistor than a XeCl excimer laser.

### EXAMPLES 1 TO 5

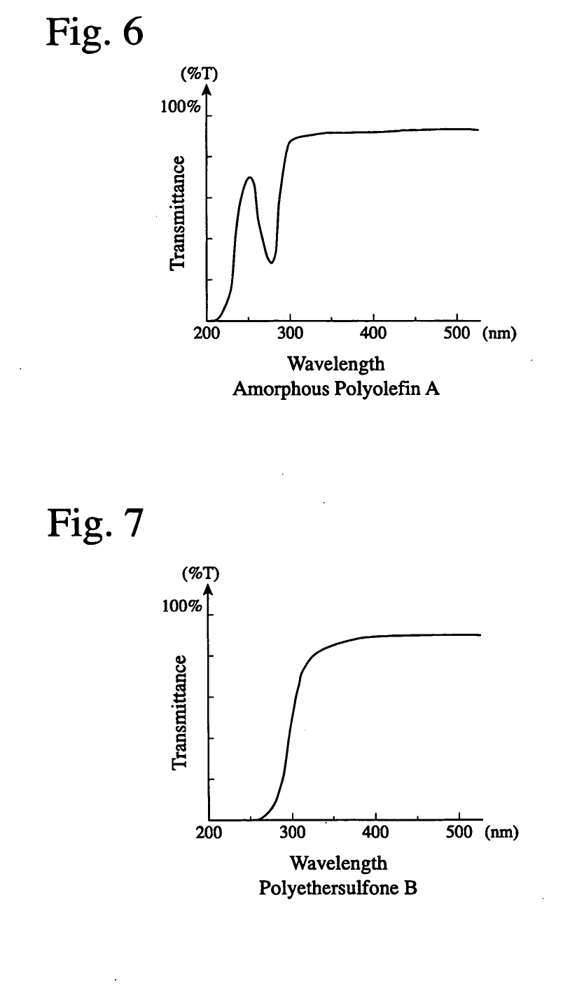

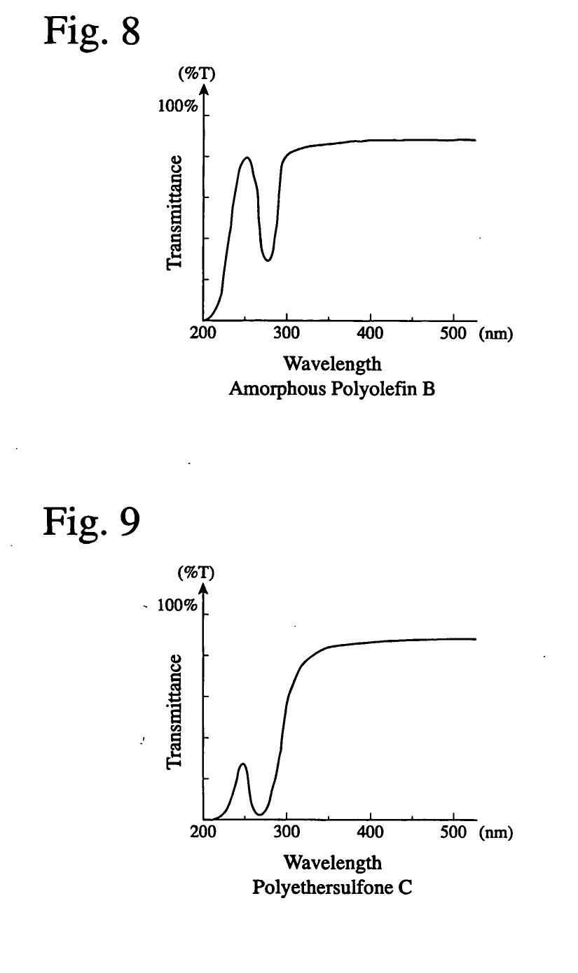

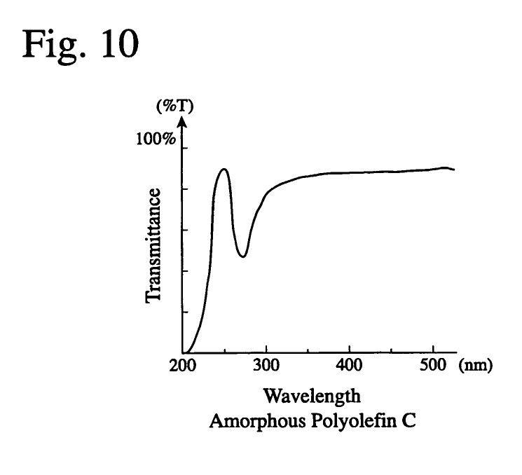

Thin-film transistors were produced and evaluated in the same manner as in Reference Example 1, except that crystalline-Si-layer-bearing substrates were produced using PES films and amorphous polyolefin films having transmission spectra shown in FIGS. 6 to 10 in place of the PES film (FS1500) under the conditions shown in Table 2. The results are shown in Table 2.

Example 1: Amorphous polyolefin A having the structure 2 (m=1-3, and n=20-30) and a number-average molecular weight of 20,000-60,000,

Example 2: Polyethersulfone B having the structure 1 (m=1-2, and n =15-20) and a number-average molecular weight of 30,000-50,000,

Example 3: Amorphous polyolefin B having the structure 2 (m=1-3, and n=10-15) and a number-average molecular weight of 20,000-60,000,

Example 4: Polyethersulfone C having the structure 1 (m=1-2, and n =5-10) and a number-average molecular weight of 30,000-50,000, and

Example 5: Amorphous polyolefin C having the structure 2 (m=1-2, and n=7-8) and a number-average molecular weight of 20,000-60,000.

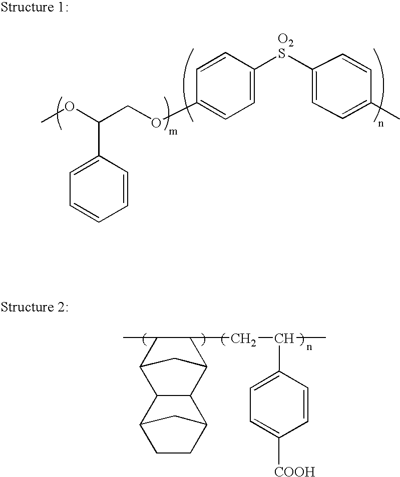

The syntheses of the above PES films and amorphous polyolefin films were conducted as follows:

(1) Polyethersulfone B and C Having the Structure 1

The following two compounds were copolymerized with varied ratios. 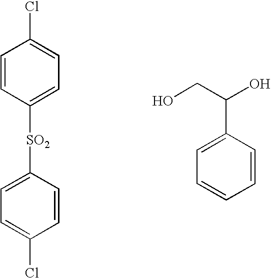
(2) Amorphous Polyolefins A, B and C Having the Structure 2

The addition polymerization of tetracycledodecene and p-carboxy styrene was conducted according to the method described in JP 10-120768 A.

TABLE 2

| | | Thickness of | | Laser- | Laser | Carrier |
|---|---|---|---|---|---|---|
| | | Amorphous Si | Type of | Overlapping | Frequency | Mobility |
| | Sample No. | Layer (nm) | Laser | Ratio (%) | (Hz) | (cm²/V · s) |
| Ref. | 1 | 150 | XeCl | 80 | 200 | Damaged⁽¹⁾ |
| Ex. 1 | 2 | 50 | XeCl | 80 | 200 | Damaged⁽¹⁾ |
| | 3 | 80 | XeCl | 80 | 200 | Damaged⁽¹⁾ |
| | 4 | 150 | XeCl | 80 | 200 | Damaged⁽¹⁾ |
| | 29 | 150 | KrF | 99 | 200 | Damaged⁽¹⁾ |
| | 30 | 80 | KrF | 99 | 200 | Damaged⁽¹⁾ |
| | 31 | 50 | KrF | 99 | 200 | Damaged⁽¹⁾ |
| | 32 | 30 | KrF | 99 | 200 | Damaged⁽¹⁾ |
| Ex. 1 | 33 | 150 | XeCl | 85 | 200 | 32 |
| | 34 | 80 | XeCl | 85 | 200 | 58 |
| | 35 | 50 | XeCl | 85 | 200 | 99 |
| | 36 | 30 | XeCl | 85 | 200 | 112 |
| | 37 | 150 | XeCl | 90 | 200 | Damaged⁽¹⁾ |
| | 38 | 150 | KrF | 85 | 200 | 35 |
| | 39 | 80 | KrF | 85 | 200 | 61 |
| | 40 | 50 | KrF | 85 | 200 | 102 |
| | 41 | 30 | KrF | 85 | 200 | 139 |
| | 42 | 150 | KrF | 90 | 200 | Damaged⁽¹⁾ |
| Ex. 2 | 43 | 150 | XeCl | 80 | 200 | 24 |
| | 44 | 80 | XeCl | 80 | 200 | 46 |
| | 45 | 50 | XeCl | 80 | 200 | 79 |
| | 46 | 30 | XeCl | 80 | 200 | 99 |
| | 47 | 150 | XeCl | 85 | 200 | Damaged⁽¹⁾ |
| | 48 | 150 | KrF | 80 | 200 | 35 |
| | 49 | 80 | KrF | 80 | 200 | Damaged⁽¹⁾ |
| | 50 | 50 | KrF | 80 | 200 | Damaged⁽¹⁾ |
| | 51 | 30 | KrF | 80 | 200 | Damaged⁽¹⁾ |
| Ex. 3 | 52 | 150 | XeCl | 95 | 200 | 47 |
| | 53 | 80 | XeCl | 95 | 200 | 71 |
| | 54 | 50 | XeCl | 95 | 200 | 109 |
| | 55 | 30 | XeCl | 95 | 200 | 138 |
| | 56 | 150 | XeCl | 99 | 200 | Damaged⁽¹⁾ |
| | 57 | 150 | KrF | 95 | 200 | 68 |
| | 58 | 80 | KrF | 95 | 200 | 76 |
| | 59 | 50 | KrF | 95 | 200 | 118 |
| | 60 | 30 | KrF | 95 | 200 | 152 |
| | 61 | 150 | KrF | 99 | 200 | Damaged⁽¹⁾ |
| Ex. 4 | 62 | 150 | XeCl | 90 | 200 | 100 |
| | 63 | 80 | XeCl | 90 | 200 | 120 |
| | 64 | 50 | XeCl | 90 | 200 | 140 |
| | 65 | 30 | XeCl | 90 | 200 | 150 |
| | 66 | 150 | XeCl | 95 | 200 | Damaged⁽¹⁾ |
| | 67 | 150 | KrF | 80 | 200 | 34 |
| | 68 | 80 | KrF | 80 | 200 | 42 |
| | 69 | 50 | KrF | 80 | 200 | Damaged⁽¹⁾ |
| | 70 | 30 | KrF | 80 | 200 | Damaged⁽¹⁾ |
| Ex. 5 | 71 | 150 | XeCl | 99 | 200 | 59 |
| | 72 | 80 | XeCl | 99 | 200 | 89 |
| | 73 | 50 | XeCl | 99 | 200 | 113 |
| | 74 | 30 | XeCl | 99 | 200 | 146 |
| | 75 | 150 | KrF | 99 | 200 | 85 |
| | 76 | 80 | KrF | 99 | 200 | 99 |
| | 77 | 50 | KrF | 99 | 200 | 136 |
| | 78 | 30 | KrF | 99 | 200 | 174 |

Note
⁽¹⁾Substrate was damaged.

Polyethersulfones and amorphous polyolefins used in Examples 1 to 5 had transmission spectra whose transmittance at 308 nm was higher than that of the polyethersulfone A used in Reference Example 1 (see FIGS. 1 and 6 to 10).

The comparison of Reference Example 1 using PES A substrate and Examples 2 and 4 using PES B, C substrates reveals that though all substrates were damaged at an overlapping ratio of 80% and a laser frequency of 200 Hz in Reference Example 1, no substrates were damaged under the same conditions in Example 2, and the substrates were not damaged even at an overlapping ratio of 90% in Example 4, resulting in high carrier mobility. The above results indicate that high-performance crystalline Si devices can be obtained without decreasing production efficiency, by using the crystalline-Si-layer-bearing substrate of the present invention.

The comparison of polyethersulfones and amorphous polyolefins between Reference Example 1 and Example 1, between Example 2 and Example 3, and between Example 4 and Example 5 reveals that the damage of substrates is less likely in the amorphous polyolefin substrates than in the polyethersulfone substrates. In addition, the KrF excimer laser causes less damage to substrates than the XeCl excimer laser, thereby providing better crystalline Si devices. The thin-film transistors of Example 5 using the amorphous polyolefin C had excellent characteristics free from substrate damage under any conditions evaluated.

As described above, the production method of the crystalline-Si-layer-bearing substrate according to the present invention can provide high-performance crystalline Si devices at high production efficiency, because of using a plastic substrate having transmittance of 30 to 100% to a light having a laser oscillation wavelength.

1. A method for producing a substrate having a crystalline Si layer comprising the steps of forming an amorphous Si layer on a plastic substrate, and irradiating said amorphous Si layer with a laser beam to crystallize said amorphous Si, wherein said plastic substrate has light transmittance of 30 to 100% at an oscillation wavelength of said laser beam.

2. The method of claim 1 for producing a substrate having a crystalline Si layer, wherein said amorphous Si layer has a thickness of 1 to 2000 nm.

3. The method of claim 1 for producing a substrate having a crystalline Si layer, wherein the oscillation wavelength of said laser beam is 140 to 450 nm.

4. The method of claim 1 for producing a substrate having a crystalline Si layer, wherein said laser is an excimer laser.

5. The method of claim 1 for producing a substrate having a crystalline Si layer, wherein said plastic substrate is made of amorphous polyolefin or polyethersulfone.

6. The method of claim 1 for producing a substrate having a crystalline Si layer, wherein said plastic substrate is made of a cycloolefin polymer represented by the following general formula (1): 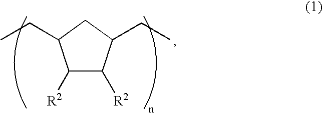
or by the following general formula (2): 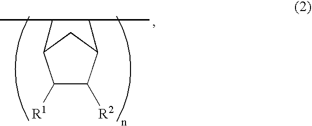
wherein R¹ and R² independently represent a hydrogen atom, a nonpolar group, a halogen atom, a hydroxyl group, an ester group, an alkoxy group, a cyano group, an amide group, an imide group or a silyl group; n represents an integer of 1 to 100,000; and R¹ and R² may be connected to each other to form a mono- or poly-cyclic ring, provided that R¹ and R² do not form a 5-membered, unsubstituted, saturated, monocyclic hydrocarbon.

7. A substrate having a crystalline Si layer produced by the method recited in claim 1.

8. The substrate of claim 7 having a crystalline Si layer, wherein said plastic substrate is provided with an insulating thin film having a thickness of 10 nm to 10 μm on at least one surface.

9. A crystalline Si device comprising the substrate of claim 7 having a crystalline Si layer.
